(19) United States
(12) Patent Application Publication
(10) Pub. No.: US 2014/0152329 A1
(43) Pub. Date: Jun. 5, 2014

(54) Insulation Monitoring Device With Measuring Circuit Interruption

(71) Applicant: Bender GmbH & Co. KG, Gruenberg (DE)

(72) Inventor: Wolfgang Hofheinz, Gruenberg (DE)

(73) Assignee: Bender GmbH & Co. KG, Gruenberg (DE)

(21) Appl. No.: 14/094,126

(22) Filed: Dec. 2, 2013

(30) Foreign Application Priority Data
Dec. 4, 2012 (DE) 10 2012 222 251.0

(51) Int. Cl. G01R 27/02

(52) U.S. Cl. CPC G01R 27/02
USPC 324/691

(57) ABSTRACT

The invention relates to an insulation monitoring device that forms a measuring circuit with an unearthed IT power supply system for monitoring an insulation resistance, wherein the measuring circuit can be interrupted by a breaker device arranged in the insulation monitoring device.

Furthermore, the invention relates to a method for performing an initial and/or repeated test of an insulation resistance in an unearthed IT power supply system and for monitoring the insulation resistance by means of an insulation monitoring device. For performing the initial and/or repeated test, the measuring circuit is interrupted by way of a manual switching act that activates a breaker device arranged in the insulation monitoring device.

The invention relates to an insulation monitoring device that is installed between active conductors of an IT power supply system and a protective earth and that forms a measuring circuit with the unearthed IT power supply system for monitoring an insulation resistance.

Furthermore, the invention relates to a method for performing an initial and/or repeated test of an insulation resistance in an unearthed IT power supply system and for monitoring the insulation resistance by means of an insulation monitoring device that is installed between active conductors of the IT power supply system and a protective earth, comprising the method steps of: performing the initial and repeated test, wherein a measuring circuit formed by the insulation monitoring device and the IT power supply system is interrupted, and monitoring the insulation resistance by means of the insulation monitoring device while the measuring circuit is closed.

In order to ensure a high availability and operational safety of the electrical power supply and to guarantee personnel safety in the area of electrical systems, power supply networks are increasingly used whose active conductors are separated from the earth potential. Operating rooms in medically used areas, photovoltaic systems or auxiliary circuits for machine systems and railway installations are examples to be mentioned in this context.

In this kind of power supply network, called unearthed IT-system, an active conductor can present an insulation fault without the running operation of the system having to be interrupted since, due to the ideally infinitely high impedance value between conductor and earth, no closed circuit can be formed in this first fault case.

to This consideration shows that the insulation resistance in the network to be monitored, including the insulation resistances of all operating equipment connected thereto against earth (insulation resistance), has to be monitored at all times, as set out in DIN standard VDE 0100-410 (VDE 0100-410). By means of a continuous insulation monitoring of the unearthed IT system, a drop in the insulation resistance can be detected and reported in time.

In addition, DIN standard VDE 0100-600 (VDE 0100-600) contains requirements regarding an initial test after completion of a new electrical system or after enhancements or changes of existing systems by way of inspection, testing and measuring. When testing, the insulation resistance of the system is to be measured according to section 61.3.1 b) of DIN standard VDE 0100-600 (VDE 0100-600). This measurement is to be performed with direct current voltages of 250 V to 1000 V, wherein the measuring voltage is selected as a function of the height of the nominal network voltage of the system to be tested. Since the insulation resistance has to be measured with predetermined accuracy, the insulation monitoring device, which is required by standard and thus built-in, must be separated—with its own alternating or direct current resistance (Zᵢ, Rᵢ) according to DIN EN 61557-8—from earth or from the protective earth connection when measuring IT systems so as to avoid measured value distortions. Otherwise, if the insulation resistance measuring device is not disconnected, damage to the device cannot be precluded.

The work necessary for disconnecting the insulation monitoring device requires enormous effort in terms of time and manual labor and may only be performed by a certified electrician. Once the initial and possibly a repeated test is completed, the insulation monitoring device is to be duly reconnected so as to comply with the required safety objective according to DIN standard VDE 0100-410 (VDE 0100-410) and to guarantee a continuous monitoring of the insulation resistance.

So far, the added effort in the initial test of the electrical system has been accepted in most cases. If the insulation monitoring device is not disconnected, it becomes obvious that, besides possible damage to the device, a test of the actual insulation resistance is impossible because of the alternating or direct current internal resistance of the insulation monitoring device or that distorted measured values render the test useless.

Therefore, it is the task of the present invention to carry out the measurement of the insulation resistance of an unearthed IT power supply system, which is installed according to standards, more effectively in terms of the work invested and in a more reliable manner in the course of an initial test.

The task is solved in connection with the preamble of claim 1 by a breaker device arranged in the insulation monitoring device for interrupting the measuring circuit.

According to the invention, the insulation monitoring device comprises a breaker device, which is arranged in a shared structural unit and which causes an interruption of the measuring circuit formed by the insulation monitoring device and the IT system. By activating the breaker device, the connection that is formed by the insulation monitoring device between the active conductors of the network and the protective earth is interrupted. The manual connecting work necessary in measuring the actual insulation resistance in the course of an initial test of the unearthed IT power supply system in order to separate the insulation monitoring device from the active conductors or from the protective earth and to reconnect it again once the test is complete thus is omitted. Apart from the time saved in this way, the electrical safety of the IT system is increased since human error in the form of inadequately performed connecting and disconnecting work is largely precluded.

The insulation monitoring device according to the invention with the integrated breaker device can be used not only in an initial test but also, advantageously, in repeated tests according to DIN VDE 0105-100/A1 (VDE 0105-100/A1).

In an enhanced embodiment, the breaker device comprises a relay contact or an electronic semiconductor switching element as switching means. The electrical connection between the insulation monitoring device and the protective earth is preferably interrupted by one or more relay contacts. Alternatively, the measuring circuit can also be interrupted by one or more electronic semiconductor switching elements.

Advantageously, the switching means of the breaker device is implemented redundantly. For safety considerations, the switching means can be configured to be redundant.

It has proven functional to provide an input device at the insulation monitoring device for manually entering switching information, which causes the interruption and/or a closing of the measuring circuit by the breaker device. Via the input device, the breaker device can be activated or deactivated and thus cause the interruption or the closing of the measuring circuit of the insulation monitoring device. In a simple embodiment, the input device is a switch or button and the switching information is simply a single switching impulse. For safety considerations and to avoid erroneous activations, a keyboard in connection with the input of a key combination or a touch screen can be provided for entering a defined character sequence.

In addition to the manual input at the insulation monitoring device, an interface for transmitting an external signal for the interruption and/or the closing of the measuring circuit by the breaker device has proven to be advantageous. By transmitting an external signal via the interface arranged in the insulation monitoring device, the measuring circuit can be interrupted and/or closed remotely from a superordinate control station, for example.

Advantageously, the insulation monitoring device comprises an electrical energy storage unit, which is preferably embodied as a capacitor or as a battery. Since the insulation resistance measurement performed in the course of the initial or repeated test is carried out in the switched-off state of the electrical system, it has to be possible to disconnect the insulation monitoring device also in a disconnected state of the IT power supply system. For this purpose, electrical energy storage units such as batteries or capacitors are to be installed in the insulation monitoring device.

Preferably, the insulation monitoring device comprises a signal and control unit that signals the interrupted state of the measuring circuit. A signal and control unit is provided in order to signal the interrupted state of the measuring circuit, i.e. a decoupled insulation monitoring device, during the initial or repeated test, and, if necessary, to output a warning.

Furthermore, the signal and control unit is embodied such that it causes an automatic closing of the measuring circuit. The signal and control unit can thus take on the task of, for example, closing the measuring circuit, i.e. reconnecting the insulation monitoring device, in a time-controlled manner so as to ensure the required continuous monitoring of the insulation resistance.

With regard to a method, the underlying task is solved in connection with the preamble of claim 10 in that for performing the initial and/or repeated test, the interruption of the measuring circuit takes place by means of a manual switching act that activates a breaker device arranged in the insulation monitoring device.

The basic though of the present invention lies in activating the disconnection of the insulation monitoring device by an uncomplicated manual switching act instead of performing extensive and time-consuming connecting work. In contrast to the connecting work, the switching act does not require extensive effort in terms of time and manual labor and thus leads to a saving of time and costs in the initial and repeated test of the electrical system. Since the measuring circuit is actually interrupted by the integrated breaker device and not by manual connecting work, it is also ensured that the insulation monitoring device is separated completely from the active conductors and/or from the protective earth and again duly reconnected thereto after the initial and repeated test.

Preferably, the manual switching act is carried out by entering switching information at the insulation monitoring device. For example, the switching act can consist of the actuation of a switch or button or it can take place by entering a character sequence on an input keyboard or on a touch screen.

It has proven advantageous for the manual switching act to take place remotely by way of a signal that is received via an interface by the insulation monitoring device. In this way, the interruption of the measuring circuit can be triggered from a place that is remote from the place of installation of the insulation monitoring device, for instance from a central control station.

Appropriately, the interrupted state of the measuring circuit is signaled. Thus, the system operator is always informed about the monitoring state of the electrical system and is alerted to a reconnection of the insulation monitoring device.

The signaling can not only be transmitted via a signal device at the insulation monitoring device itself but also via the afore-mentioned interface so as to register centrally, for example, which system sections currently are not subject to continuous insulation resistance monitoring.

In a further embodiment, the measuring circuit closes automatically. Alternatively to a manually performed reconnection of the insulation monitoring device, an automatic reconnection can be carried out, which to is based on a timer control, for example.

Further advantageous embodiment features arise from the following description and from the drawing, which illustrates a preferred embodiment of the invention with the aid of an example.

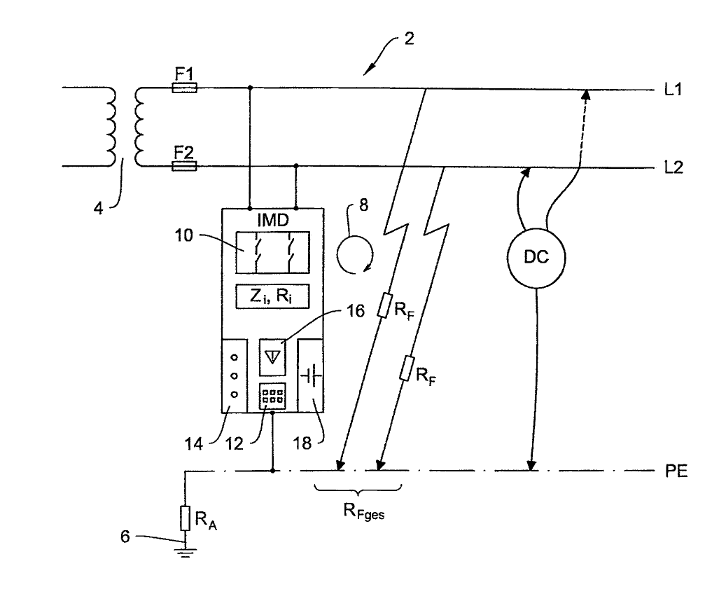

FIG. 1: shows a basic circuit diagram of the insulation monitoring including an initial test of an unearthed IT power supply system.

In the basic circuit diagram according to FIG. 1, an unearthed IT power supply system 2 is illustrated with two active conductors L1 and L2, which each have a fuse device F1, F2 and are supplied via a transformer 4. The active conductors L1, L2 are insulated against the protective earth PE (earth) so that in the ideal case an infinitely high impedance value, designated insulation resistance R_{F}, in the fault case also called insulation fault R_{F}, occurs between the respective conductor L1, L2 and earth PE. The protective earth PE is connected to the solid ground via an earth electrode 6 and together with the resistance of the earth electrode 6 it forms an earth resistance R_{A}.

In practice, an actual total insulation resistance R_{Fges} occurs, which, according to DIN standard VDE 0100-600 (VDE 0100-600), is subject to an initial test upon completion of a new electrical system. Said initial test takes place as a function of the nominal network voltage at a direct current voltage DC of 250 V to 1000 V and is symbolized in the right-hand part of the illustrated IT power supply system, the parallel connection of the insulation faults (insulation resistances) R_{F} resulting in the actual total insulation resistance R_{Fges}.

FIG. 1 further shows an insulation monitoring device IMD according to the invention, which is connected to the conductors L1, L2 and to the protective earth PE and which serves to continuously monitor the insulation resistance R_{F} so as to detect early on a drop in the insulation resistance R_{F} that may pose a safety risk. The insulation monitoring device

IMD together with the IT power supply system 2 including the total insulation resistance R_{Fges} forms a measuring circuit 8 in which an evaluable measuring current occurs in correspondence to the total insulation resistance R_{Fges}.

Since the insulation monitoring device IMD has a complex-valued inner resistance Zᵢ, with an ohmic part Rᵢ, the measured value of the actual total insulation resistance R_{Fges} to be determined in the course of the initial test may be heavily distorted if the measuring circuit 8 stays closed with the insulation monitoring device IMD and if the insulation monitoring device IMD thus remains between the active conductors L1, L2 and the protective earth PE. Hence, according to the invention, a breaker device 10 is arranged in the insulation monitoring device IMD, by means of which the measuring circuit 8 can be interrupted so that the inner resistance Zᵢ of the insulation monitoring device IMD does not take effect. In the course of the initial test and/or of the repeated test, the actual total insulation resistance R_{Fges} can thus be determined without being distorted by the inner resistance Zᵢ of the insulation monitoring device IMD.

For initializing the interruption of the measuring circuit 8 by a manual switching act, an input device 12 is provided at the insulation monitoring device IMD. For safety reasons, it may be necessary to enter a specific character sequence as switching information via a keyboard or a touch screen. The switching act can also be performed from a remote location and transmitted via signal transmission to the insulation monitoring device IMD, which in that case comprises an interface 14 for receiving the external signal.

A signal and control unit 16 signals the current connection state of the insulation monitoring device (measuring circuit closed/interrupted) and thus indicates a currently not insulation-monitored IT power supply system 2 due to an interrupted measuring circuit 8. Moreover, the signal and control unit 16 can allow the measuring circuit 8 to close automatically, for example in connection with a programmable time interval.

Since the measurement of the actual total insulation resistance R_{Fges} takes place in the switched-off state of the IT power supply system 2, the insulation monitoring device IMD comprises an electrical energy storage unit 18, embodied as a battery in this example, so as to be able to interrupt the measuring circuit 8 also in a disconnected state of the insulation monitoring device IMD.

1. An insulation monitoring device (IMD) that is installed between active conductors (L1, L2) of an IT power supply system (2) and a protective earth (PE) and forms a measuring circuit (8) with the unearthed IT power supply system (2) for monitoring an insulation resistance (R_{F}),
characterized by
a breaker device (10) arranged in the insulation monitoring device (IMD) for interrupting the measuring circuit (8).

2. The insulation monitoring device (IMD) according to claim 1, characterized in that
the breaker device (10) comprises a relay contact or an electronic semiconductor switching element as switching means.

3. The insulation monitoring device (IMD) according to claim 2, characterized in that
the switching means of the breaker device (10) is configured to be redundant.

4. The insulation monitoring device (IMD) according to any of the claims 1 to 3,
characterized by
an input device (12) for manually entering a switching information that triggers the interruption and/or a closing of the measuring circuit (8) by the breaker device (10).

5. The insulation monitoring device (IMD) according to any of the claims 1 to 4,
characterized by
an interface (14) for transmitting an external signal for the interruption and/or for the closing of the measuring circuit (8) by the breaker device (10).

6. The insulation monitoring device (IMD) according to any of the claims 1 to 5,
characterized by
an electrical energy storage unit (18).

7. The insulation monitoring device (IMD) according to claim 6, characterized in that
the electrical energy storage unit (18) is implemented as a capacitor or as a battery.

8. The insulation monitoring device (IMD) according to any of the claims 1 to 7,
characterized by
a signal and control unit (16) that signals the interrupted state of the measuring circuit (8).

9. The insulation monitoring device (IMD) according to claim 8, characterized in that
the signal and control unit (16) is embodied such that it causes the measuring circuit (8) to close automatically.

10. A method for carrying out an initial and repeated test of an insulation resistance (R_{F}) in an unearthed IT power supply system (2) and for monitoring the insulation resistance (R_{F}) with an insulation monitoring device (IMD) that is installed between active conductors (L1, L2) of the IT power supply system (2) and a protective earth (PE), comprising the method steps of:
carrying out the initial and/or repeated test, wherein a measuring circuit (8) formed by the insulation monitoring device (IMD) and the IT power supply system (2) is interrupted, and
monitoring the insulation resistance (R_{F}) by means of the insulation monitoring device (IMD) while the measuring circuit (8) is closed,
characterized in that
for performing the initial and/or repeated test, the measuring circuit (8) is interrupted by means of a manual switching act that activates a breaker device (10) arranged in the insulation monitoring device (IMD).

11. The method according to claim 10,
characterized in that
the manual switching act takes place in that a switching information is entered at the insulation monitoring device (IMD).

12. The method according to claim 11,
characterized in that
the manual switching act takes place remotely by way of a signal that is received via an interface (14) by the insulation monitoring device (IMD).

13. The method according to any of the claims 10 to 12,
characterized in that
the interrupted state of the measuring circuit (8) is signaled.

14. The method according to any of the claims 10 to 13,
characterized in that
the measuring circuit (8) closes automatically.
